(19) United States
(12) Patent Application Publication
(10) Pub. No.: US 2016/0043249 A1
(43) Pub. Date: Feb. 11, 2016

(54) SOLAR CELL MODULE AND METHOD OF FABRICATING THE SAME

(71) Applicant: Dong Keun LEE, Seoul (KR)

(72) Inventor: Dong Keun LEE, Seoul (KR)

(73) Assignee: LG INNOTEK CO., LTD., Seoul (KR)

(21) Appl. No.: 14/885,301

(22) Filed: Oct. 16, 2015

Related U.S. Application Data
(63) Continuation of application No. 14/351,827, filed on May 22, 2014.

(30) Foreign Application Priority Data
Oct. 13, 2011 (KR) 10-2011-0104742

(51) Int. Cl. H01L 31/0352; H01L 31/02; H02S 40/34

(52) U.S. Cl. CPC H01L 31/0352; H02S 40/34; H01L 31/0201

(57) ABSTRACT

Disclosed are a solar cell module and a method of fabricating the same. The solar cell module includes a plurality of solar cells including a back electrode layer, a light absorbing layer, and a front electrode layer that are sequentially provided on a top surface of a support substrate, an inclined hole obliquely formed through the support substrate, a junction box on a bottom surface of the support substrate, and a bus bar connected to one of the solar cells and electrically connected to the junction box through the inclined hole.

### CROSS-REFERENCE TO RELATED APPLICATIONS

This application is a continuation of U.S. application Ser. No. 14/351,827, filed May 22, 2014, which is the U.S. national stage application of International Patent Application No. PCT/KR2012/004886, filed Jun. 20, 2012, which claims priority to Korean Patent Application No. 10-2011-0104742, filed Oct. 13, 2011, which are hereby incorporated by reference in their entirety.

### BACKGROUND

### Technical Field

The embodiment relates to a solar cell module and a method of fabricating the same.

### BACKGROUND OF THE INVENTION

Solar cells may be defined as devices to convert light energy into electric energy by using a photovoltaic effect of generating electrons when light is incident onto a P-N junction diode. The solar cell may be classified into a silicon solar cell, a compound semiconductor solar cell mainly including a group I-III-VI compound or a group III-V compound, a dye-sensitized solar cell, and an organic solar cell according to materials constituting the junction diode.

The minimum unit of the solar cell is a cell. In general, one cell generates a very small voltage of about 0.5V to about 0.6V. Therefore, a panel-shape structure of connecting a plurality of cells to each other in series on a substrate to generate voltages in a range of several voltages to several hundreds of voltages is referred to as a module, and a structure having several modules installed in a frame is referred to as a solar cell apparatus.

Typically, the solar cell apparatus has a structure of glass/filling material (ethylene vinyl acetate, EVA)/solar cell module/filling material (EVA)/surface material (back sheet).

In general, the glass includes low-iron tempered glass. The glass must represent high light transmittance and be treated to reduce the surface reflection loss of incident light. The EVA used as the filling material is interposed between the front/rear side of the solar cell and the back sheet to protect a fragile solar cell device. When the EVA is exposed to UV light for a long time, the EVA may be discolored, and the moisture proof performance of the EVA may be degraded. Accordingly, when the module is fabricated, it is important to select a process suitable for the characteristic of the EVA sheet so that the life span of the module can be increased, and the reliability of the module can be ensured. The back sheet is placed on the rear side of the solar cell module. The back sheet must represent superior adhesive strength between layers, must be easily handled, and must protect the solar cell device from an external environment.

In general, the solar cell apparatus includes conductors (bus bar) connected to the solar cells while serving as an anode and a cathode, respectively. Thereafter, the bus bars are connected to a junction box provided on the bottom surface of the substrate, so that the solar cell apparatus can output the power generated from the solar cells to the outside.

Meanwhile, in the solar cell apparatus according to the related art, the bus bars are significantly bent when the bus bars are electrically connected to the junction box. The bending of the bus bars interrupts the flow of electrons in the bus bars, so that the efficiency of the solar cell may be degraded.

### DETAILED DESCRIPTION

### Technical Problem

The embodiment provides a solar cell module capable of improving photoelectric efficiency by forming inclined holes in the support substrate to improve the flow of electrons in the bus bar, and a method of fabricating the same.

### Technical Solution

According to the embodiment, there is provided a solar cell module which includes a plurality of solar cells including a back electrode layer, a light absorbing layer, and a front electrode layer that are sequentially provided on a top surface of a support substrate, an inclined hole obliquely formed through the support substrate, a junction box on a bottom surface of the support substrate, and a bus bar connected to one of the solar cells and electrically connected to the junction box through the inclined hole.

According to the embodiment, there is provided a method of fabricating a solar cell module. The method includes forming an inclined hole in a support substrate, forming solar cells on the support substrate, forming a bus bar on the solar cells, and allowing the bus bar to pass through the inclined hole, and electrically connecting the bus bar to a junction box provided on a bottom surface of the support substrate.

### Advantageous Effects

As described above, according to the solar cell module of the embodiment, the bending of the bus bar passing through the inclined hole can be minimized by obliquely forming the inclined hole through the support substrate. Therefore, in the solar cell module, the flow of electrons can be optimized, and resistance caused by the bending of the bus bar can be reduced. Therefore, according to the solar cell module of the embodiment, the photoelectric conversion efficiency can be improved.

In addition, according to the solar cell module of the embodiment, the size of the junction box provided on the bottom surface of the support substrate can be minimized through the above structure. Therefore, the appearance of the solar cell module can be improved, and the fabricating cost can be reduced.

### DESCRIPTION OF THE DRAWINGS

FIG. 1 is a plan view showing a solar cell module according to the embodiment;

FIG. 2 is a rear view showing the solar cell module according to the embodiment;

FIG. 3 is a sectional view taken along line A-A′ of the solar cell module according to the embodiment;

FIG. 4 is a sectional view showing the solar cell module taken along line B-B′ of the solar cell module; and

FIG. 5 is a sectional view showing a support substrate including an inclined hole according to the embodiment.

### MODE FOR INVENTION

In the description of the embodiments, it will be understood that, when a substrate, a layer, a film, or an electrode is referred to as being “on” or “under” another substrate, another layer, or another film, or another electrode, it can be “directly” or “indirectly” on the other substrate, the other layer, the other film, or the other electrode, or one or more intervening layers may also be present. Such a position of the layer has been described with reference to the drawings. The thickness and size of each layer shown in the drawings may be exaggerated, omitted or schematically drawn for the purpose of convenience or clarity. In addition, the size of elements does not utterly reflect an actual size.

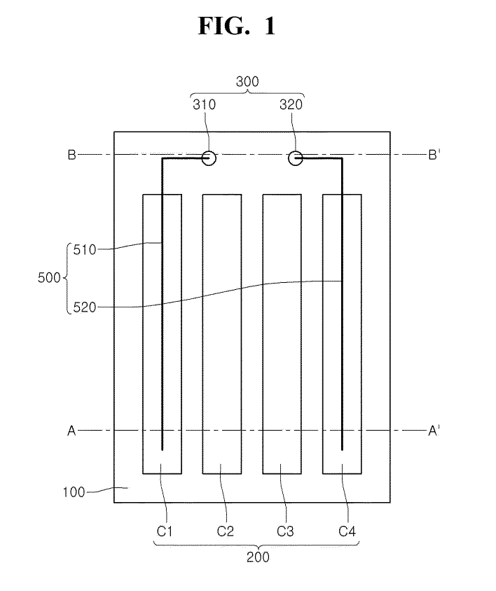

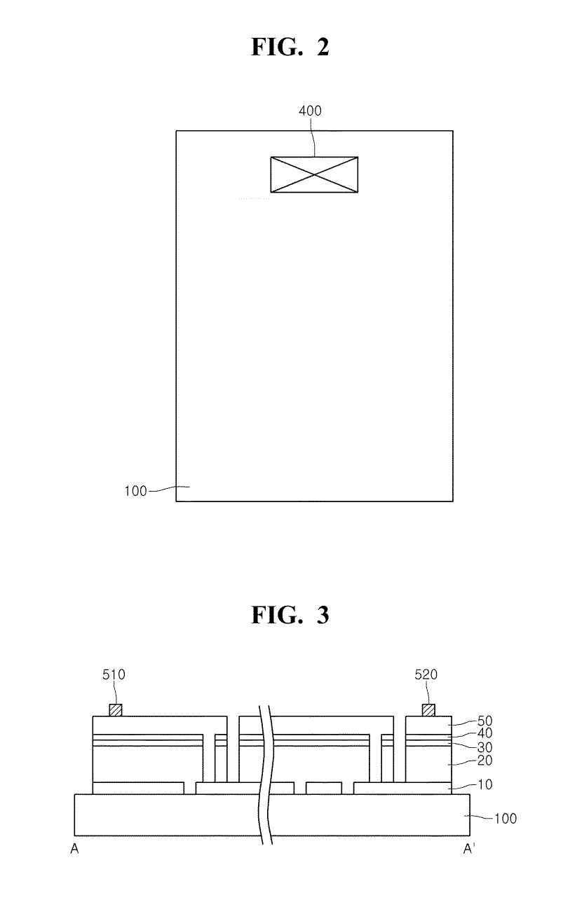

FIG. 1 is a plan view showing a solar cell module according to the embodiment, FIG. 2 is a rear view showing the solar cell module according to the embodiment, and FIG. 3 is a sectional view taken along line A-A′ of the solar cell module according to the embodiment.

Referring to FIGS. 1 and 2, the solar cell module according to the embodiment includes a support substrate 100, solar cells 200, inclined holes 300, a junction box 400, and bus bars 500.

The support substrate 100 has a plate shape and supports the solar cells 200, the inclined holes 300, the junction box 400, and the bus bars 500.

The support substrate 100 may include a rigid panel or a flexible panel. In addition, the support substrate 100 may include an insulator. For example, the support substrate 100 may include a glass substrate, a plastic substrate, or a metallic substrate. In more detail, the support substrate 100 may include a soda lime glass substrate. In addition, the support substrate 100 may include a ceramic substrate including alumina, stainless steel, or polymer having a flexible property.

The solar cells 200 are formed on the support substrate 100. The solar cells 200 include a plurality of solar cells C1, C2, C3, . . . , and Cn. Although FIG. 1 shows only four solar cells, the embodiment is not limited thereto. In other words, a plurality of solar cells may be provided.

The solar cells C1, C2, C3, . . . , and Cn are electrically connected to each other. Therefore, the solar cells 200 may convert the sunlight into electrical energy. For example, although the solar cells C1, C2, C3, . . . , and Cn are electrically connected to each other in series, the embodiment is not limited thereto. In addition, the solar cells C1, C2, C3, . . . , and Cn extend in one direction while being parallel to each other.

Each solar cell 200 may include a solar cell including a group I-III-IV semiconductor compound such as a CIGS-based solar cell, a silicon-based solar cell, or a dye-sensitized solar cell, but the embodiment is not limited thereto.

In more detail, as shown in FIG. 3, the solar cells 200 may include a solar cell including a group I-III-IV based semiconductor compound. In this case, each solar cell 200 may include a back electrode layer 10 on the support substrate 100, a light absorbing layer 20 on the back electrode layer 10, a buffer layer 30 on the light absorbing layer 20, a high resistance buffer layer 40 on the buffer layer 30, a front electrode layer 50 on the high resistance buffer layer 40.

The back electrode layer 10 is provided on the support substrate 100. The back electrode layer 10 is a conductive layer. The back electrode layer 10 may include one selected from the group consisting of molybdenum (Mo), gold (Au), aluminum (Al), chrome (C), tungsten (W), and copper (Cu). Among then, since the molybdenum (Mo) makes a less thermal expansion coefficient with the support substrate 100 when comparing with other elements, the Mo represents a superior adhesive property to prevent the delamination phenomenon.

The light absorbing layer 20 is provided on the back electrode layer 10. The light absorbing layer 20 includes a group I-III-VI compound. For example, the light absorbing layer 20 may have the CIGSS (Cu(IN,Ga)(Se,S)2) crystal structure, the CISS (Cu(IN)(Se,S)2) crystal structure or the CGSS (Cu(Ga)(Se,S)2) crystal structure.

The buffer layer 30 is provided on the light absorbing layer 20. The buffer layer 30 may include CdS, ZnS, InXSY or InXSeYZn(O, OH). The energy bandgap of the buffer layer 30 may be in the range of about 2.2 eV to about 2.4 eV.

The high resistance buffer layer 40 is provided on the buffer layer 30. The high resistance buffer layer 40 includes i-ZnO which is not doped with impurities. The energy bandgap of the high resistance buffer layer 40 may be in the range of about 3.1 eV to about 3.3 eV. In addition, the high resistance buffer layer 40 may be omitted.

The front electrode layer 50 may be provided on the light absorbing layer 20. For example, the front electrode layer 50 may directly make contact with the high resistance buffer layer 40 on the light absorbing layer 20. The front electrode layer 500 may include a transparent conductive material.

In addition, the front electrode layer 50 may have the characteristics of an N type semiconductor. In this case, the front electrode layer 50 forms an N type semiconductor with the buffer layer 30 to make PN junction with the light absorbing layer 20 serving as a P type semiconductor layer. For example, the front electrode layer 50 may include aluminum (Al) doped zinc oxide (AZO).

Meanwhile, although not shown in drawings, a polymer resin layer (not shown) and a protective panel (not shown) may be additionally formed on the solar cells 200.

The polymer resin layer (not shown) is provided on the solar cells 200. In more detail, the polymer resin layer is interposed between the solar cells 200 and the protective panel. The polymer resin layer not only can improve the adhesive strength between the solar cells 200 and the protective panel, but also can protect the solar cells 200 from external shocks. For example, the polymer resin layer may include an ethylene vinyl acetate (EVA) film, but the embodiment is not limited thereto.

The protective panel (not shown) is provided on the polymer resin layer. The protective panel protects the solar cells 200 from external physical shock and/or foreign matters. The protective panel is transparent and may include tempered glass. In this case, the tempered glass may include low iron tempered glass having the less contents of the iron.

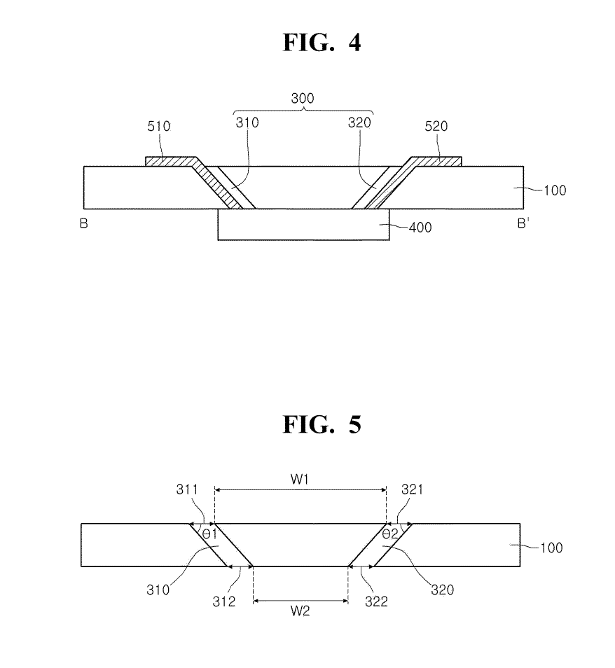

FIG. 4 is a sectional view the solar cell module taken along line B-B′ of FIG. 2. FIG. 5 is a sectional view showing the support substrate 100 having inclined holes 300 according to the embodiment.

Each inclined hole 300 serves as a passage allowing the bus bar 500 to pass through the support substrate 100. The bus bar 500 can be electrically connected to the junction box 400 provided at the bottom surface of the support substrate 100 through the inclined hole 300.

Referring to FIGS. 4 and 5, the inclined hole 300 is obliquely formed through the support substrate 100. In more detail, the inclined hole 300 may be obliquely formed through the support substrate while extending from an outer portion of the support substrate 100 to the central portion of a bottom surface of the support substrate 100. As described above, according to the solar cell module of the embodiment, an inclined hole is obliquely formed through the support substrate 100, thereby minimizing the bending of the bus bar 500 passing through the inclined hole 300. Therefore, the solar cell module can optimize the flow of electrons and reduce resistance caused by the bending.

In addition, the inclined hole 300 may be formed in a non-active area (NA) of the support substrate 100. In the whole description, the term “non-active area” refers to an area that does not exert an influence on the photoelectric conversion of the solar cell.

The inclined hole 300 may include a first inclined hole 310, through which the first bus bar 520 passes, and a second inclined hole 320, through which the second bus bar 520 passes. As shown in FIGS. 4 and 5, the first and second inclined holes 310 and 320 may be provided in opposition to each other, but the embodiment is not limited thereto.

The first and second inclined holes 310 and 320 are inclined with respect to the support substrate 100. For example, an angle θ1 at which the first inclined hole 310 is inclined with respect to the support substrate 100 may be in the range of about 20° to about 40°. An angle θ2 at which the second inclined hole 310 is inclined with respect to the support substrate 100 may be in the range of about 20° to about 40°, but the embodiment is not limited thereto. In addition, the angles θ1 and θ2 may be identical to or different from each other. In other words, the angle θ1 at which the first inclined hole 310 is inclined may be identical to or different from the angle θ2 at which the second inclined hole 320 is inclined.

In more detail, the first inclined hole 310 includes a 1st opening 311 formed in the top surface of the support substrate 100 and a 1st' opening 312 formed in the bottom surface of the support substrate 100. In addition, the second inclined hole 320 may include a 2nd opening 321 formed in the top surface of the support substrate 100 and a 2nd' opening 322 formed in the bottom surface of the support substrate 100.

The first and second inclined holes 310 and 320 may be spaced apart from each other. In more detail, the 1st opening 311 and the 2nd opening 321 formed in the top surface of the support substrate 100 may be spaced apart from each other by a first distance W1. In addition, the 1st' opening 312 and the 2nd' opening 322 formed in the bottom surface of the support substrate 100 may be spaced apart from each other by a second distance W2.

As described above, the inclined hole 300 is formed through the support substrate while obliquely extending from the outer portion of the support substrate 100 to the central portion of the bottom surface of the support substrate 100. Therefore, the first distance W1 is greater than the second distance W2. For example, the ratio of the first distance W1 to the second distance W2 may be in the range of 1.5:1 to 10:1, but the embodiment is not limited thereto.

In order to form the inclined hole 300, various schemes of perforating the support substrate 100 generally known in the art can be employed. For example, the inclined hole 300 may be formed through a mechanical scheme or formed by irradiating a laser into the support substrate 100. In addition, a step of forming the inclined hole 300 may be performed before the solar cells 200 are formed on the support substrate 100 or after the solar cells 200 have been formed on the support substrate 100, but the embodiment is not limited thereto.

The junction box 400 may be provided on the bottom surface of the support substrate 100. The junction box 400 may be electrically connected to the bus bar 500 and may receive the circuit board on which diodes are mounted.

The junction box 400 may discharge electrons generated from the light absorbing layer 20 by the sunlight to the outside. In other words, the electrons generated from the light absorbing layer 20 may be output to the outside through the light absorbing layer 20, the bus bar 500 passing through the inclined hole 300, and the junction box 400.

In more detail, the junction box 400 may be provided in the NA of the bottom surface of the support substrate 100. In addition, the junction box 400 may be formed corresponding to the inclined hole 300. For example, the junction box 400 may be provided on the 1st' opening 312 and the 2nd' opening 322 formed in the bottom surface of the support substrate 100.

As described above, the second distance W2 between the 1st' opening 312 and the 2nd' opening 322 provided in the bottom surface of the support substrate 100 is shorter than the first distance W1 between the 1st opening 311 and the 2nd opening 321 provided in the top surface of the support substrate 100. Accordingly, the junction box 400 provided on the 1st' opening 312 and the 2nd' opening 322 may be manufactured in a smaller size when comparing with a junction box according to the related art. In other words, according to the solar cell module of the embodiment, the size of the junction box may be minimized through the above structure. Accordingly, the appearance of the solar cell module can be improved, and the fabricating cost of the solar cell module can be saved.

The bus bar 500 is connected to one of the solar cells C1, C2, C3, . . . , and Cn. In more detail, the bus bar 500 is electrically connected to one of the solar cells C1, C2, C3, . . . , and Cn through the direct contact with the one of the solar cells C1, C2, C3, . . . , and Cn. For example, the bus bar 500 may directly make contact with the front electrode layer 50 in one of the solar cells C1, C2, C3, . . . , and Cn as shown in FIG. 3, but the embodiment is not limited thereto. For example, the bus bar 500 may directly make contact with the back electrode layer 10 in one of the solar cells C1, C2, C3, . . . , and Cn, but the embodiment is not limited thereto.

One bus bar 500 or a plurality of bus bars 500 may be provided. In more detail, two bus bars 500 may be provided. For example, the bus bar 500 includes a first bus bar 510 directly making contact with a top surface of one of the solar cells C1, C2, C3, . . . , and Cn and a second bus bar 520 directly making contact with a top surface of another of the solar cells C1, C2, C3, . . . , and Cn. In this case, the first bus bar 510 and the second bus bar 520 serve as an anode and a cathode, respectively.

The bus bar 500 is electrically connected with the junction box 500 through the inclined hole 300. In more detail, the bus bar 500 may electrically connect the junction box 500 to the solar cells C1, C2, C3, . . . , and Cn through the inclined hole 300.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A solar cell module comprising:
a plurality of solar cells including a back electrode layer, a light absorbing layer, and a front electrode layer that are sequentially provided on a top surface of a support substrate; and
an inclined hole obliquely formed though the support substrate while extending from an outer portion of the top surface of the support substrate to a central portion of the bottom surface of the support substrate;
wherein the inclined hole is formed in a non-active area of the support substrate;
wherein an inclination angle of the inclined hole with respect to the support substrate is in a range of 20° to 40°.

2. The solar cell module of claim 1, further comprising a junction box on a bottom surface of the support substrate; and
a bus bar connected to one of the solar cells and electrically connected to the junction box through the inclined hole.

3. The solar cell module of claim 2, wherein the bus bar comprises:
a first bus bar directly making contact with a top surface of one of the solar cells; and
a second bus bar directly making contact with a top surface of another of the solar cells.

4. The solar cell module of claim 3, wherein the inclined hole comprises a first inclined hole through which the first bus bar passes, and a second inclined hole through which the second bus bar passes.

5. The solar cell module of claim 4, wherein the first inclined hole comprises a 1st opening formed in the top surface of the support substrate and a 1st' opening formed in the bottom surface of the support substrate, and
the second inclined hole comprises a 2nd opening formed in the top surface of the support substrate and a 2nd' opening formed in the bottom surface of the support substrate.

6. The solar cell module of claim 5, wherein the first inclined hole is provided in opposition to the second inclined hole.

7. The solar cell module of claim 5, wherein a first distance between the 1st opening and the 2nd opening is greater than a second distance between the 1st' opening and the 2nd' opening.

8. The solar cell module of claim 7, wherein a ration of the first distance to the second distance is in a range of 1.5:1 to 10:1.

9. The solar cell module of claim 5, wherein the junction box is provided on the 1st' opening and the 2nd' opening.
